(19) United States
(12) Patent Application Publication
(10) Pub. No.: US 2026/0340243 A1
(43) Pub. Date: Oct. 29, 2026

(54) SYSTEM AND METHOD FOR ELECTRONIC DESIGN AUTOMATION

(71) Applicants: Tokyo Electron Limited, Tokyo (JP); SiClarity, Inc., Sunnyvale, CA (US)

(72) Inventors: Eric Panning, Portand, OR (US); Sreekar Bathula, Palo Alto, CA (US); Jeffrey Smith, Albany, NY (US); Zia Alan Shafi, Albany, NY (US); H. Jim Fulford, Marianna, FL (US); Anton deVilliers, Albany, NY (US)

(21) Appl. No.: 19/653,635

(22) Filed: Apr. 21, 2026

Related U.S. Application Data
(60) Provisional application No. 63/793,169, filed on Apr. 23, 2025.

(51) Int. Cl. G06F 30/31; G06F 30/323; G06F 30/398; G06N 3/042

(52) U.S. Cl. CPC G06F 30/31; G06F 30/323; G06F 30/398; G06N 3/042

(57) ABSTRACT

A method includes receiving an initial netlist and initial design rules (DRs) of a standard cell, generating, using an artificial intelligence/machine learning (AI/ML) placement model, candidate layouts of the standard cell, determining, using an AI/ML predictive model, initial values of metric function (MF) for the candidate layouts, identifying a subset of the candidate layouts that have the initial values of MF within a target range, scaling one or more initial DRs to determine one or more scaled DRs, generating, using the AI/ML placement model, candidate scaled layouts of the standard cell, determining, using the AI/ML predictive model, scaled values of MF for the candidate scaled layouts, identifying a subset of the candidate scaled layouts that have the scaled values of MF within a scaled target range, and ranking the one or more scaled DRs based on an impact of each scaled DR on the scaled values of MF.

### CROSS-REFERENCE TO RELATED APPLICATIONS

This application claims the benefit of U.S. Provisional Application No. 63/793,169, filed on Apr. 23, 2025, which application is hereby incorporated herein by reference.

### TECHNICAL FIELD

The present disclosure relates generally to electronic design automation, and more particularly to systems and methods for identifying design rule constraints and optimum scaling paths for standard cell circuit layouts using artificial intelligence/machine learning techniques.

### BACKGROUND

Standard cells are fundamental building blocks for complementary metal oxide semiconductor (CMOS) based logic circuits. Each standard cell implements a basic circuit function, such as an inverter, a logic gate, a multiplexer, or a flip-flop, and is arranged as a physical layout of transistors, contacts, and metal interconnect lines according to a set of design rules specified in a process design kit. When developing new technology nodes, engineers seek to improve power consumption, switching speed performance, area, and cost of standard cells by scaling one or more of these design rules. A technology node can include hundreds of individual design rules governing dimensions such as gate pitch, contact sizes, metal track widths, and spacings between various layout elements.

Evaluating the impact of scaling a particular design rule on standard cell performance currently involves a sequence of steps using multiple tools, including technology computer aided design (TCAD) device simulation, manual circuit layout, parasitic resistance and capacitance extraction, and circuit simulation. This conventional approach typically considers only a single layout permutation out of potentially hundreds of thousands of electrically compliant configurations for a given standard cell circuit. As a result, the conventional approach may not identify the layout permutation that yields the best performance under the scaled design rules, and development resources can be directed toward scaling activities that do not produce the most significant improvements.

### SUMMARY

In accordance with an embodiment, a method for electronic design automation, the method includes receiving a process design kit including an initial netlist and initial design rules of a standard cell for creating an integrated circuit; generating, using an artificial intelligence/machine learning (AI/ML) placement model, a set of candidate layouts of the standard cell; determining, using an AI/ML predictive model, initial values of a metric function for the set of candidate layouts; identifying a subset of the set of candidate layouts that have the initial values of the metric function within a target range; scaling one or more initial design rules to determine one or more scaled design rules; generating, using the AI/ML placement model, a set of candidate scaled layouts of the standard cell; determining, using the AI/ML predictive model, scaled values of the metric function for the set of candidate scaled layouts; identifying a subset of the set of candidate scaled layouts that have the scaled values of the metric function within a scaled target range; and ranking the one or more scaled design rules based on an impact of each scaled design rule on the scaled values of the metric function.

In accordance with another embodiment, a method for electronic design automation, the method includes receiving a process design kit including an initial netlist and initial design rules of a standard cell for creating an integrated circuit; generating, using an artificial intelligence/machine learning (AI/ML) placement model, a set of candidate layouts of the standard cell; determining, using an AI/ML predictive model, initial values of a metric function for the set of candidate layouts; identifying a subset of the set of candidate layouts that have the initial values of the metric function within a target range; iteratively scaling the initial design rules until a scaled target range equals a desired target range, wherein each iterative scaling process includes: scaling one or more initial design rules to determine one or more scaled design rules; generating, using the AI/ML placement model, a set of candidate scaled layouts of the standard cell; determining, using the AI/ML predictive model, scaled values of the metric function for the set of candidate scaled layouts; and identifying a subset of the set of candidate scaled layouts that have the scaled values of the metric function within a scaled target range; identifying one or more candidate scaled layouts having values of the metric function within the desired target range as one or more scaled layouts of the standard cell; identifying respective values of the metric function for the one or more scaled layouts; updating the initial design rules based on one or more scaled design rules used to generate the one or more scaled layouts of the standard cell; and ranking the one or more scaled design rules based on an impact of each scaled design rule on the scaled values of the metric function.

In accordance with yet another embodiment, a system for electronic design automation, the system includes one or more memories configured to store: an artificial intelligence/machine learning (AI/ML) placement model; an AI/ML predictive model; and instructions; and one or more processors operably coupled to the one or more memories and configured to execute the instructions, where, upon execution of the instructions by the one or more processors, the one or more processors are configured to: receive a process design kit including an initial netlist and initial design rules of a standard cell for creating an integrated circuit; generate, using the AI/ML placement model, a set of candidate layouts of the standard cell; determine, using the AI/ML predictive model, initial values of a metric function for the set of candidate layouts; identify a subset of the set of candidate layouts that have the initial values of the metric function within a target range; scale one or more initial design rules to determine one or more scaled design rules; generate, using the AI/ML placement model, a set of candidate scaled layouts of the standard cell; determine, using the AI/ML predictive model, scaled values of the metric function for the set of candidate scaled layouts; identify a subset of the set of candidate scaled layouts that have the scaled values of the metric function within a scaled target range; and rank the one or more scaled design rules based on an impact of each scaled design rule on the scaled values of the metric function.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 illustrates a block diagram of a system for electronic design automation, in accordance with various embodiments;

FIG. 2 illustrates a diagram of a single-row standard cell layout, in accordance with various embodiments;

FIG. 3 illustrates a graph showing cell height as a number of tracks after scaling design rules, in accordance with various embodiments;

FIG. 4 illustrates a graph showing inverter gate delay after scaling design rules, in accordance with various embodiments; and

FIGS. 5A and 5B illustrate a flowchart of a method for electronic design automation, in accordance with various embodiments.

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope.

While various embodiments of the present disclosure are described primarily in the context of identifying design rule constraints and optimum scaling paths for standard cell layouts using artificial intelligence/machine learning (AI/ML) models, it should also be appreciated that these embodiments may also apply to other areas of electronic design automation where large design spaces are explored and evaluated against multi-dimensional performance metrics. In particular, various embodiments of the present disclosure may similarly apply to block-level layout optimization, custom circuit layout generation, memory cell design, analog circuit layout, and design-technology co-optimization workflows where iterative evaluation of physical design parameters against power, performance, area, and cost metrics can benefit from AI/ML-based placement and predictive modeling.

Various embodiments of the present disclosure describe methods and systems for electronic design automation that use AI/ML models to identify design rule constraints and determine optimum scaling paths for standard cell circuit layouts. In some embodiments, a system for electronic design automation receives a process design kit comprising an initial netlist and initial design rules of a standard cell. The system uses an AI/ML placement model to generate a set of candidate layouts of the standard cell according to the initial design rules and uses an AI/ML predictive model to determine values of a metric function for the candidate layouts. The metric function can comprise a function of a power metric, a performance metric, an area metric, and a cost metric, and can be weighted to prioritize one or more of these metrics according to user preferences.

In some embodiments, the system scales one or more of the initial design rules and generates a new set of candidate scaled layouts using the AI/ML placement model. The AI/ML predictive model determines scaled values of the metric function for the candidate scaled layouts. The system identifies a subset of the candidate scaled layouts having metric function values within a scaled target range. This scaling and evaluation process can be performed iteratively, adjusting the design rules until the scaled target range equals a desired target range specified by a user. Upon reaching the desired target range, the system identifies the scaled layouts, the corresponding metric function values, and the updated design rules that enable the standard cell to achieve the desired performance target.

In some embodiments, the AI/ML predictive model can comprise a graph neural network (GNN) trained on data from a rigorous solver, enabling rapid prediction of parasitic resistance and capacitance values for each candidate layout without requiring full parasitic extraction runs. In various embodiments, the AI/ML placement model can employ a graph neural network, reinforcement learning, Monte Carlo simulation, or Bayesian methods to efficiently explore the vast design space of layout permutations.

Various embodiments of the present disclosure enable evaluation of many tens of thousands of layout permutations across multiple design rule combinations, which would be impractical using conventional rigorous simulation methods. The result is an identification and prioritization of which design rules, when scaled, produce the most significant improvement in power, performance, area, and cost metrics, allowing process integration teams to direct development efforts toward the highest-impact activities. These and additional details are further discussed below.

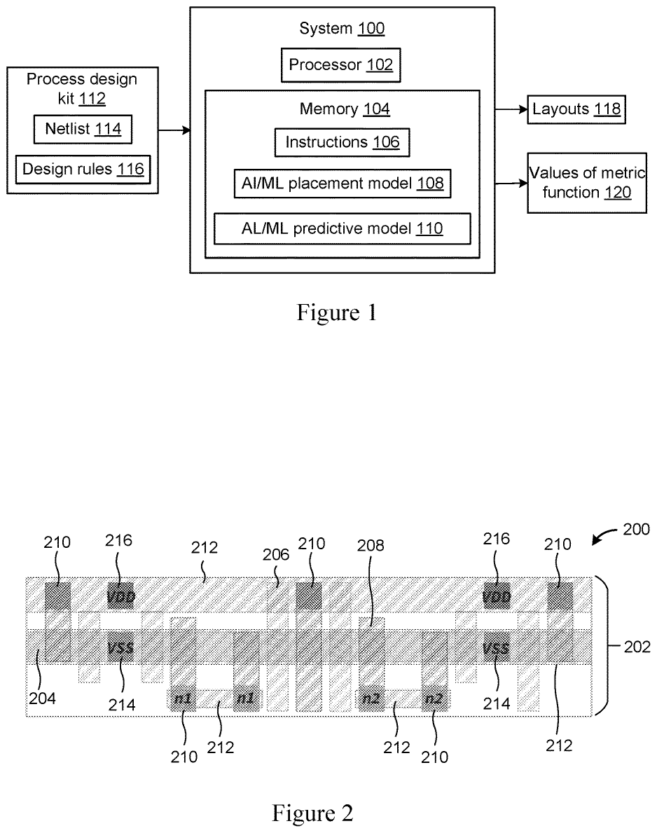

FIG. 1 illustrates a block diagram of a system 100 for electronic design automation, in accordance with various embodiments. The system 100 includes a processor 102 operably coupled to a memory 104. In some embodiments, processor 102 may comprise one or more processors such as a central processing unit (CPU), a graphics processing unit (GPU), a field-programmable gate array (FPGA), an application-specific integrated circuit (ASIC), or any combination thereof. In some embodiments, memory 104 may comprise one or more memories, each of which may comprise a non-transitory computer-readable medium such as random-access memory (RAM), read-only memory (ROM), flash memory, a hard disk drive, or any combination thereof. The memory 104 can be configured to store instructions 106, an AI/ML placement model 108, and an AI/ML predictive model 110. The processor 102 can execute the instructions 106, AI/ML placement model 108, and AI/ML predictive model 110 to perform operations for generating and evaluating standard cell layouts based on inputs received by the system 100. In an embodiment, AI/ML placement model 108 and AI/ML predictive model 110 comprise GNN models.

In some embodiments, the system 100 receives a process design kit (PDK) 112 as input. The process design kit 112 includes a netlist 114 and design rules 116. The netlist 114 is an electrical description of a circuit, such as a standard cell circuit used as a building component for complementary metal oxide semiconductor (CMOS) based logic circuits. Standard cell circuits can include, for example, inverters, logic gates, adders, multiplexers, flip-flops, or the like. The design rules 116 define physical constraints for laying out the standard cell circuit, such as element widths, spacing between elements, contacted poly pitch in a horizontal direction, and number of metal tracks in a vertical direction. The process design kit 112 can correspond to various transistor technologies, including gate all around (GAA) transistors, complementary field effect transistors (CFETs), fin field effect transistors (FinFETs), planar CMOS transistors, or the like.

In some embodiments, the AI/ML placement model 108 is configured to generate candidate layouts of the standard cell based on the netlist 114 and the design rules 116. For a given electrical circuit and set of design rule constraints, there can be many hundreds of thousands of different electrically compliant layout permutations. The AI/ML placement model 108 can explore this large design space efficiently. In various embodiments, the AI/ML placement model 108 can comprise a GNN model, a Monte Carlo simulation model, a Bayesian model, a reinforcement learning agent, or the like. The AI/ML placement model 108 can use a GNN optimization approach in which the electrical design of the standard cell is converted to a graph, with transistor sources and drains represented as nodes and connections between elements represented as edges.

In some embodiments, the AI/ML predictive model 110 is configured to determine values of a metric function 120 for the candidate layouts generated by the AI/ML placement model 108. The metric function can comprise a function of a power metric, a performance metric, an area metric, and a cost metric. These metrics are commonly referred to as Power, Performance, Area, and Cost (PPAC) metrics and are used to assess and compare different CMOS technologies. In an embodiment, the performance metric can comprise parasitic resistance and capacitance of a respective layout. In various embodiments, the AI/ML predictive model 110 can comprise a GNN model. The AI/ML predictive model 110 can be trained using a training set generated by a rigorous solver such as, for example, a parasitic extraction (PEX) tool that extracts resistance and capacitance elements from a circuit layout. Traditional PEX extraction for a single layout can take many hours. The AI/ML predictive model 110, once trained, can predict parasitic resistance and capacitance values rapidly without requiring the rigorous extraction process for each new layout.

The metric function can be chosen such that one or more of the power metric, the performance metric, the area metric, and the cost metric may be prioritized over the others. For example, the metric function can be a linear combination of the individual metrics, where each metric is multiplied by a respective weight. A user can increase the weights of the prioritized metrics relative to the weights of the remaining metrics. In an embodiment, a user who prioritizes area reduction can assign a larger weight to the area metric, causing the system 100 to favor candidate layouts that minimize area. In another embodiment, a user who prioritizes performance improvement can assign a larger weight to the performance metric. Setting the weights of all metrics other than the area metric to zero reduces the metric function to a purely area-driven optimization. The metric function is not limited to linear combinations and can comprise other formulations that reflect the relative importance of the individual metrics.

The system 100 produces layouts 118 and values of metric function 120 as outputs. The layouts 118 can include one or more candidate layouts or scaled layouts of the standard cell that satisfy specified target criteria. The values of metric function 120 can include the corresponding PPAC metric values for the output layouts 118.

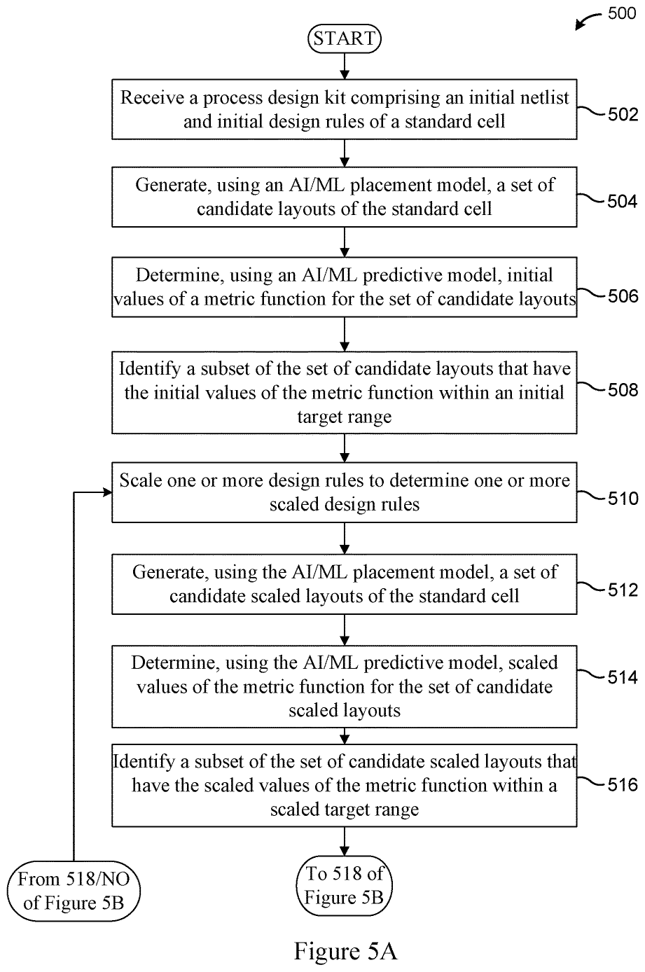

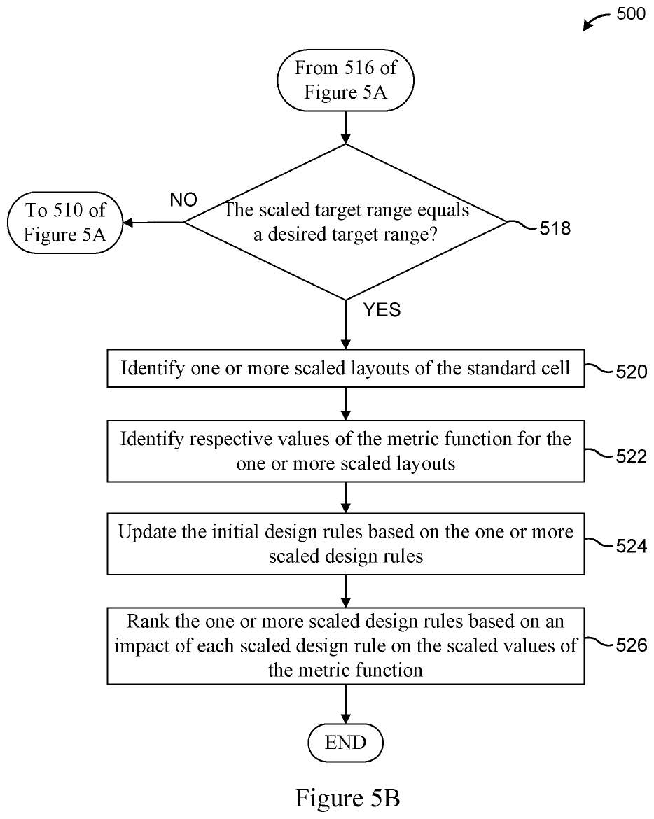

In some embodiments, the system 100 can be configured to perform a method 500 for electronic design automation, as described in further detail below with respect to FIGS. 5A and 5B. In performing the method 500, the processor 102 executes the instructions 106 to receive the process design kit 112, generate candidate layouts using the AI/ML placement model 108, evaluate the candidate layouts using the AI/ML predictive model 110, and iteratively scale one or more of the design rules 116 to identify which design rules, when scaled, produce the most significant improvement in the metric function. During each iteration, the AI/ML placement model 108 generates a new set of candidate scaled layouts under the scaled design rules, and the AI/ML predictive model 110 determines updated values of the metric function for the candidate scaled layouts. The system 100 continues iterating until a scaled target range equals a desired target range specified by the user. The resulting scaled design rules and associated layouts 118, together with the corresponding values of metric function 120, enable process integration teams to prioritize development efforts toward activities that yield the greatest return in PPAC improvement.

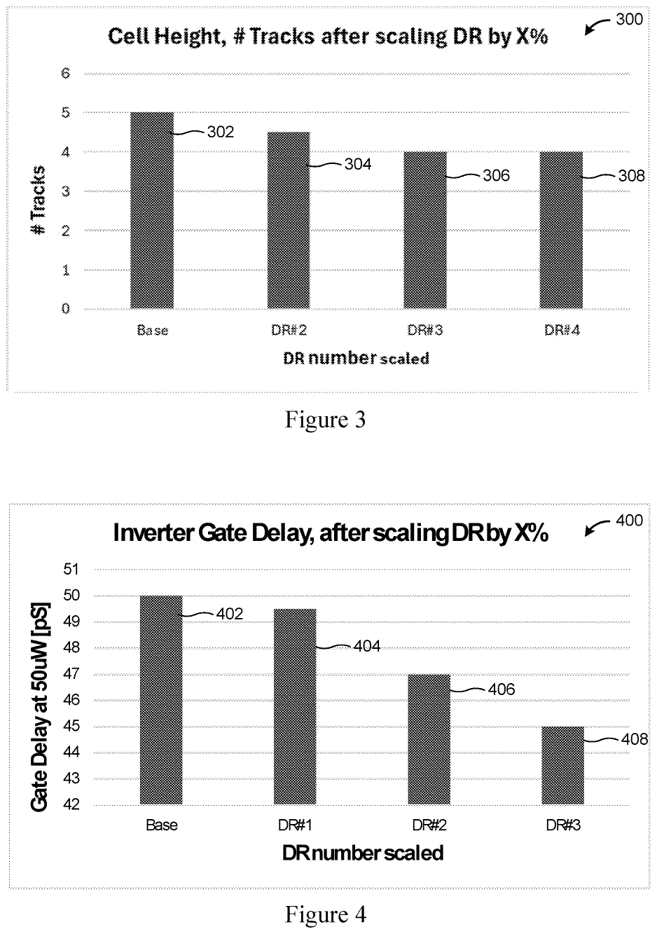

FIG. 2 illustrates a diagram of a single-row standard cell layout 200, in accordance with various embodiments. The single-row standard cell layout 200 is an example of one of the candidate layouts that can be generated by the AI/ML placement model 108 of the system 100 described above with respect to FIG. 1. The single-row standard cell layout 200 represents a physical arrangement of circuit elements for a standard cell, such as an inverter, a logic gate, or another basic circuit element defined by the netlist 114 of FIG. 1. The values of metric function 120 described with respect to FIGS. 3 and 4 can be derived from layouts such as the single-row standard cell layout 200. In the illustrated embodiments, the standard cell layout 200 has a single-row configuration. In other embodiments, the standard cell layout 200 can have a multiple-row configuration (e.g., two-row, three-row, etc.).

The single-row standard cell layout 200 includes a cell row 202. The cell row 202 contains a complementary pair of transistors, including an N-type metal oxide semiconductor (NMOS) transistor and a P-type metal oxide semiconductor (PMOS) transistor, arranged within the height of a single row. In some embodiments, the VDD node 216 provides a positive power supply connection and the VSS node 214 provides a ground connection for the standard cell.

The single-row standard cell layout 200 can include one or more active regions 204 extending within the cell row 202. Each active region 204 can correspond to a fin of a FinFET transistor, nanostructures of a GAA transistor, or a channel region of another transistor type. The active region 204 is where the channel of the transistor is formed. The process design kit 112 of FIG. 1 can specify the dimensions and spacing of the active regions 204 as part of the design rules 116.

One or more gates 206 are disposed across the active regions 204. Each gate 206 wraps around or overlaps the active region 204 to form the gate structure of the transistor. The gate 206 controls current flow through the channel formed in the active region 204. In GAA transistor technology, the gate 206 wraps around the nanosheet or nanowire structures of the active region 204.

Source/drain regions 208 are disposed on either side of each gate 206 along the active region 204. Each source/drain region 208 provides an electrical terminal for the transistor. The source/drain regions 208 are formed where the active region 204 is not covered by the gate 206.

Source/drain contacts 210 are disposed on respective source/drain regions 208. Each source/drain contact 210 provides an electrical connection to the underlying source/drain region 208. The source/drain contacts 210 enable vertical connections from the transistor level to metal interconnect layers above. The single-row standard cell layout 200 includes multiple source/drain contacts 210 distributed across the cell row 202 to provide connections to both NMOS and PMOS transistors.

Metal lines 212 are disposed above the transistor structures in the single-row standard cell layout 200. The metal lines 212 run horizontally and provide interconnection between circuit elements within the standard cell and connections to adjacent standard cells. The metal lines 212 can include connections to the VDD node 216, the VSS node 214, and internal netlist nodes. The number of metal lines 212 that can fit within the height of the cell row 202 is referred to as the number of tracks, which is a measure of the standard cell area. The design rules 116 of FIG. 1 can specify the width and spacing of the metal lines 212.

Internal netlist nodes, such as nodes labeled n1 and n2 in FIG. 2, represent electrical connections between transistor terminals within the standard cell. Each internal netlist node corresponds to a node in the netlist 114 of FIG. 1. For example, a node n1 can represent a connection between a source of one transistor and a drain of another transistor. The arrangement of these internal connections is one of the aspects that varies among the many possible layout permutations for a given standard cell circuit.

The area of the single-row standard cell layout 200 can be defined by the contacted poly pitch (CPP) in the horizontal direction and the number of metal tracks in the vertical direction. For any given standard cell circuit defined by the netlist 114 and constrained by the design rules 116, there can be many hundreds of thousands of different electrically compliant layout permutations. Each permutation arranges the active regions 204, gates 206, source/drain regions 208, source/drain contacts 210, and metal lines 212 in a different configuration while maintaining electrical equivalence to the netlist 114. The AI/ML placement model 108 and the AI/ML predictive model 110 of FIG. 1 can generate and evaluate these permutations to identify layouts that optimize the metric function.

FIG. 3 illustrates a graph showing cell height, expressed as a number of tracks, after scaling design rules by a percentage, in accordance with various embodiments. The graph 300 is an example of the values of metric function 120 that can be output by the system 100 described above with respect to FIG. 1. The graph 300 represents the area metric component of the metric function for candidate scaled layouts generated during performance of the method 500 described below with respect to FIGS. 5A and 5B. FIG. 4, described further below, provides a complementary view of the same scaling exercise by showing the performance metric component.

The horizontal axis of the graph 300 represents different design rules that have been scaled. The vertical axis represents the number of tracks, which is a measure of the standard cell height and thus the area of the standard cell. As described above with respect to FIG. 2, the number of tracks corresponds to the number of metal lines 212 that can fit within the height of the cell row 202 of a standard cell layout. A reduction in the number of tracks indicates a reduction in the standard cell area.

A bar 302 represents the baseline number of tracks for the standard cell under the initial, unscaled design rules 116 (see FIG. 1). In the example shown, the baseline is approximately five tracks. A bar 304 represents the number of tracks after scaling a second design rule (DR #2) by a specified percentage. In the example shown, scaling DR #2 reduces the number of tracks to approximately four and a half tracks. A bar 306 represents the number of tracks after scaling a third design rule (DR #3) by the specified percentage, resulting in approximately four tracks. A bar 308 represents the number of tracks after scaling a fourth design rule (DR #4) by the specified percentage, resulting in approximately four tracks. In some embodiments, each of the design rules DR #2, DR #3, and D #4 may represent any design rule specified in the technology design kit, such as but not limited to the minimum width of an interconnect line, the size of a via or contact, the contacted gate pitch, and the like.

The graph 300 demonstrates that scaling different design rules results in different amounts of area reduction. In the example shown, scaling DR #3 or DR #4 produces the largest reduction in the number of tracks, while scaling DR #2 produces smaller reduction. The graph 300 also demonstrates that scaling certain design rules may have no meaningful effect on the standard cell area because other design rules remain constraining. The AI/ML placement model 108 of FIG. 1 can identify these constraints by generating new candidate scaled layouts for each set of scaled design rules and determining whether the scaled design rules enable the standard cell layout to fit within a smaller area bound.

The graph 300 can be generated for different standard cell circuit types, such as inverters, logic gates, multiplexers, and flip-flops, so that the scaling analysis is representative of multiple different layout types rather than a single circuit. The graph 300 can also be generated for different scaling percentages of the same design rule, producing a family of results that characterize the sensitivity of the area metric to each design rule.

FIG. 4 illustrates a graph 400 showing inverter gate delay after scaling different design rules by a percentage, in accordance with various embodiments. The graph 400 is another example of the values of metric function 120 that can be output by the system 100 described above with respect to FIG. 1. While the graph 300 of FIG. 3 shows the impact of design rule scaling on the area metric (number of tracks), the graph 400 shows the impact of design rule scaling on the performance metric (gate delay). Together, FIGS. 3 and 4 illustrate how the system 100 of FIG. 1 produces multi-dimensional metric function outputs that enable identification of optimum design rule scaling paths.

The horizontal axis of the graph 400 represents different design rules that have been scaled. The vertical axis represents gate delay at a specified power level (50 microwatts) in picoseconds (ps). In other embodiments, gate delay may be measured at any desired power level. Gate delay is a measure of the switching speed of a standard cell circuit and is determined from the parasitic resistance and capacitance of the layout. As described above with respect to FIG. 1, the AI/ML predictive model 110 can predict parasitic resistance and capacitance values for each candidate layout, from which the gate delay can be derived. A reduction in gate delay indicates an improvement in the performance metric.

A bar 402 represents the baseline gate delay for the standard cell under the initial, unscaled design rules 116 (see FIG. 1). A bar 404 represents the gate delay after scaling a first design rule (DR #1) by a specified percentage. A bar 406 represents the gate delay after scaling a second design rule (DR #2) by the specified percentage. A bar 408 represents the gate delay after scaling a third design rule (DR #3) by the specified percentage.

The graph 400 demonstrates that scaling different design rules results in different amounts of performance improvement. In the example shown, scaling DR #3 produces the largest reduction in gate delay, while scaling DR #1 produces a comparatively small improvement. The relative impact of each design rule on gate delay can differ from the relative impact of each design rule on the number of tracks shown in FIG. 3. For example, a design rule that produces a large area reduction may produce only modest performance improvement, or vice versa. The combined impact of scaling a design rule on both resistance and capacitance can be non-obvious because some scaling changes affect resistance and capacitance in opposite directions. The AI/ML predictive model 110 of FIG. 1 can quantify these combined effects rapidly for each candidate scaled layout.

FIGS. 5A and 5B illustrate a flowchart of a method 500 for electronic design automation, in accordance with various embodiments. Although shown in a particular sequence, it should be appreciated that the steps of method 500 may be performed in any suitable sequence. Furthermore, one or more steps of method 500 may be omitted. Method 500 may be performed by system 100 of FIG. 1. In some embodiments, a processor (e.g., processor 102 of FIG. 1) of the system 100 executes instructions 106, AI/ML placements model 108, and AI/ML predictive model 110 to perform steps 502-526 of method 500.

Method 500 starts with step 502, where a processor (e.g., processor 102 of FIG. 1) of a system for electronic design automation (e.g., system 100 of FIG. 1) receives a process design kit (e.g., process design kit 112 of FIG. 1) comprising an initial netlist (e.g., netlist 114 of FIG. 1) and initial design rules (e.g., design rules 116 of FIG. 1) of a standard cell (e.g., single-row standard cell layout 200 of FIG. 2) for creating an integrated circuit, as described in FIGS. 1 and 2.

In step 504, the processor generates, using an AI/ML placement model (e.g., AI/ML placement model 108 of FIG. 1), a set of candidate layouts of the standard cell. The candidate layouts are electrically compliant arrangements of the circuit elements defined by the initial netlist, generated according to the initial design rules.

In step 506, the processor determines, using an AI/ML predictive model (e.g., AI/ML predictive model 110 of FIG. 1), initial values of a metric function (e.g., values of metric function 120 of FIG. 1) for the set of candidate layouts, as described in FIG. 1. The initial values of the metric function establish a baseline of achievable performance under the initial design rules.

In step 508, the processor identifies a subset of the candidate layouts that have the initial values of the metric function within an initial target range. The initial target range defines an acceptable range of metric function values for the candidate layouts under the initial design rules. Candidate layouts that fall outside the target range can be rejected. The subset of candidate layouts within the initial target range represents the baseline set of layouts that satisfy the current performance criteria.

In step 510, the processor scales one or more of the initial design rules to determine one more scaled design rules. Scaling a design rule can include increasing or decreasing a physical dimension defined by the design rule, such as reducing a gate pitch, reducing a contact size, reducing a metal interconnect width, or reducing a spacing between elements. The initial target range can be scaled correspondingly to reflect the desired improvement in the metric function. For example, if the user specifies a target area reduction of ten percent, the target range for the area metric can be adjusted accordingly. In an embodiment, scaling can be performed for a single design rule at a time to isolate the impact of each design rule on the metric function. In another embodiment, multiple design rules can be scaled simultaneously.

In step 512, the processor generates, using the AI/ML placement model, a set of candidate scaled layouts of the standard cell. The candidate scaled layouts are generated according to the scaled design rules from step 510. Scaling a design rule introduces a new degree of freedom in the layout design space, which can enable the circuit elements to be arranged in configurations that were not possible under the initial design rules. The AI/ML placement model can explore the resulting design space to generate candidate scaled layouts that fit within the scaled area bounds.

In step 514, the processor determines, using the AI/ML predictive model (e.g., AI/ML predictive model 110 of FIG. 1), scaled values of the metric function for the set of candidate scaled layouts. The AI/ML predictive model predicts the parasitic resistance and capacitance values for each candidate scaled layout and determines the corresponding power, performance, area, and cost metrics. The scaled values of the metric function reflect the impact of the scaled design rules on the PPAC metrics. Example scaled values of the metric function are illustrated in the graph 300 of FIG. 3 (showing the area metric as number of tracks) and the graph 400 of FIG. 4 (showing the performance metric as gate delay).

In step 516, the processor identifies a subset of the candidate scaled layouts that have the scaled values of the metric function within a scaled target range. Candidate scaled layouts that do not fit within the scaled area bounds or that have metric function values outside the scaled target range can be rejected. The subset of candidate scaled layouts within the scaled target range represents the layouts that satisfy the scaled performance criteria.

In step 518, the processor determines whether the scaled target range equals a desired target range. The desired target range is specified by the user and represents the overall objective for the design rule scaling exercise. For example, the desired target range can specify a target area reduction, a target performance improvement, or a target improvement in the weighted metric function, as described above with respect to FIG. 1.

In response to determining that the scaled target range does not equal the desired target range, method 500 returns to step 510. The processor scales one or more additional design rules or further scales the previously scaled design rules, and method 500 repeats steps 512 through 518. This iterative loop enables the system to explore multiple design rule scaling combinations until the desired target range is achieved. Each iteration can scale a different design rule to isolate its individual impact, or can scale additional design rules in combination with previously scaled design rules.

In response to determining that the scaled target range equals the desired target range, method 500 proceeds to steps 520, 522, 524, and 526. In step 520, the processor identifies the subset of candidate scaled layouts that have metric function values within the desired target range as one or more scaled layouts of the standard cell. The identified scaled layouts (e.g., layouts 118 of FIG. 1) represent the optimum layout configurations under the scaled design rules.

In step 522, the processor identifies respective values of the metric function for the one or more scaled layouts. The respective values (e.g., values of metric function 120 of FIG. 1) can include the individual power, performance, area, and cost metrics as well as the weighted metric function value for each identified scaled layout. These values enable comparison and prioritization of the identified scaled layouts and their associated design rule scaling paths.

In step 524, the processor updates the initial design rules based on one or more scaled design rules used to generate the one or more scaled layouts identified in step 520. The updated design rules represent the design rule modifications that enable the standard cell to achieve the desired target range. The updated design rules and the associated scaled layouts can be used by process integration teams to prioritize development efforts toward the design rules and associated process steps that yield the greatest improvement in PPAC metrics. After performing step 524, method 500 then ends.

In step 526, the processor ranks the one or more scaled design rules based on an impact of each scaled design rule on the scaled values of the metric function. The ranking allows effective prioritization for design rules scaling, and prioritization and direction for associated process integration solutions.

Example embodiments of the disclosure are described below. Other embodiments can also be understood from the entirety of the specification as well as the claims filed herein.

Example 1. A method for electronic design automation, the method including: receiving a process design kit including an initial netlist and initial design rules of a standard cell for creating an integrated circuit; generating, using an artificial intelligence/machine learning (AI/ML) placement model, a set of candidate layouts of the standard cell; determining, using an AI/ML predictive model, initial values of a metric function for the set of candidate layouts; identifying a subset of the set of candidate layouts that have the initial values of the metric function within a target range; scaling one or more initial design rules to determine one or more scaled design rules; generating, using the AI/ML placement model, a set of candidate scaled layouts of the standard cell; determining, using the AI/ML predictive model, scaled values of the metric function for the set of candidate scaled layouts; identifying a subset of the set of candidate scaled layouts that have the scaled values of the metric function within a scaled target range; and ranking the one or more scaled design rules based on an impact of each scaled design rule on the scaled values of the metric function.

Example 2. The method of Example 1, further including: in response to determining that the scaled target range equals a desired target range: identifying the subset of the set of candidate scaled layouts as one or more scaled layouts of the standard cell; identifying respective values of the metric function for the one or more scaled layouts; and updating the initial design rules based on the one or more scaled design rules.

Example 3. The method of any of Examples 1 and 2, where the integrated circuit includes a gate all around (GAA) transistor, a complementary field effect transistor (CFET), a fin FET (FinFET), or a planar complementary metal oxide semiconductor (CMOS) transistor.

Example 4. The method of any of Examples 1 to 3, where using the AI/ML placement model includes using a Monte Carlo simulation model.

Example 5. The method of any of Examples 1 to 3, where using the AI/ML placement model includes using a Bayesian model.

Example 6. The method of any of Examples 1 to 5, further including, in response to determining that the scaled target range does not equal a desired target range, scaling the one or more scaled design rules.

Example 7. The method of any of Examples 1 to 6, where the AI/ML predictive model includes a graph neural network (GNN) model.

Example 8. The method of any of Examples 1 to 7, where the AI/ML placement model includes a graph neural network (GNN) model.

Example 9. The method of any of Examples 1 to 8, where the metric function includes a function of a power metric, a performance metric, an area metric, and a cost metric.

Example 10. The method of Example 9, where the performance metric includes parasitic resistance and capacitance of a respective layout.

Example 11. The method of any of Examples 1 to 10, further including training the AI/ML predictive model using a training set generated by a rigorous solver.

Example 12. The method of any of Examples 1 to 11, further including iteratively scaling the one or more scaled design rules until the scaled values of the metric function are within a desired target range.

Example 13. A method for electronic design automation, the method including: receiving a process design kit including an initial netlist and initial design rules of a standard cell for creating an integrated circuit; generating, using an artificial intelligence/machine learning (AI/ML) placement model, a set of candidate layouts of the standard cell; determining, using an AI/ML predictive model, initial values of a metric function for the set of candidate layouts; identifying a subset of the set of candidate layouts that have the initial values of the metric function within a target range; iteratively scaling the initial design rules until a scaled target range equals a desired target range, wherein each iterative scaling process includes: scaling one or more initial design rules to determine one or more scaled design rules; generating, using the AI/ML placement model, a set of candidate scaled layouts of the standard cell; determining, using the AI/ML predictive model, scaled values of the metric function for the set of candidate scaled layouts; and identifying a subset of the set of candidate scaled layouts that have the scaled values of the metric function within a scaled target range; identifying one or more candidate scaled layouts having values of the metric function within the desired target range as one or more scaled layouts of the standard cell; identifying respective values of the metric function for the one or more scaled layouts; updating the initial design rules based on one or more scaled design rules used to generate the one or more scaled layouts of the standard cell; and ranking the one or more scaled design rules based on an impact of each scaled design rule on the scaled values of the metric function.

Example 14. The method of Example 13, where the integrated circuit includes a gate all around (GAA) transistor, a complementary field effect transistor (CFET), a fin FET (FinFET), or a planar complementary metal oxide semiconductor (CMOS) transistor.

Example 15. The method of any of Examples 13 and 14, where using the AI/ML placement model includes using a Monte Carlo simulation model.

Example 16. The method of any of Examples 13 and 14, where using the AI/ML placement model includes using a Bayesian model.

Example 17. The method of any of Examples 13 to 16, where the AI/ML predictive model includes a graph neural network (GNN) model.

Example 18. The method of any of Examples 13 to 17, where the AI/ML placement model includes a graph neural network (GNN) model.

Example 19. The method of any of Examples 13 to 18, where the metric function includes a function of a power metric, a performance metric, an area metric, and a cost metric.

Example 20. The method of Example 19, where the performance metric includes parasitic resistance and capacitance of a respective layout.

Example 21. The method of any of Examples 13 to 20, further including training the AI/ML predictive model using a training set generated by a rigorous solver.

Example 22. A system for electronic design automation, the system including: one or more memories configured to store: an artificial intelligence/machine learning (AI/ML) placement model; an AI/ML predictive model; and instructions; and one or more processors operably coupled to the one or more memories and configured to execute the instructions, where, upon execution of the instructions by the one or more processors, the one or more processors are configured to: receive a process design kit including an initial netlist and initial design rules of a standard cell for creating an integrated circuit; generate, using the AI/ML placement model, a set of candidate layouts of the standard cell; determine, using the AI/ML predictive model, initial values of a metric function for the set of candidate layouts; identify a subset of the set of candidate layouts that have the initial values of the metric function within a target range; scale one or more initial design rules to determine one or more scaled design rules; generate, using the AI/ML placement model, a set of candidate scaled layouts of the standard cell; determine, using the AI/ML predictive model, scaled values of the metric function for the set of candidate scaled layouts; identify a subset of the set of candidate scaled layouts that have the scaled values of the metric function within a scaled target range; and rank the one or more scaled design rules based on an impact of each scaled design rule on the scaled values of the metric function.

Example 23. The system of Example 22, where the one or more processors are further configured to: in response to determining that the scaled target range equals a desired target range: identify the subset of the set of candidate scaled layouts as one or more scaled layouts of the standard cell; identify respective values of the metric function for the one or more scaled layouts; and update the initial design rules based on the one or more scaled design rules.

Example 24. The system of any of Examples 22 and 23, where the integrated circuit includes a gate all around (GAA) transistor, a complementary field effect transistor (CFET), a fin FET (FinFET), or a planar complementary metal oxide semiconductor (CMOS) transistor.

Example 25. The system of any of Examples 22 to 24, where using the AI/ML placement model includes using a Monte Carlo simulation model.

Example 26. The system of any of Examples 22 to 24, where using the AI/ML placement model includes using a Bayesian model.

Example 27. The system of any of Examples 22 to 26, where the one or more processors are further configured to, in response to determining that the scaled target range does not equal a desired target range, scale the one or more scaled design rules.

Example 28. The system of any of Examples 22 to 27, where the AI/ML predictive model includes a graph neural network (GNN) model.

Example 29. The system of any of Examples 22 to 28, where the AI/ML placement model includes a graph neural network (GNN) model.

Example 30. The system of any of Examples 22 to 29, where the metric function includes a function of a power metric, a performance metric, an area metric, and a cost metric.

Example 31. The system of Example 30, where the performance metric includes parasitic resistance and capacitance of a respective layout.

Example 32. The system of any of Examples 22 to 31, where the one or more processors are further configured to train the AI/ML predictive model using a training set generated by a rigorous solver.

Example 33. The system of any of Examples 22 to 32, where the one or more processors are further configured to iteratively scale the one or more scaled design rules until the scaled values of the metric function are within a desired target range.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

The order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present disclosure can be embodied and viewed in many different ways.

“Substrate,” “target substrate,” “structure,” or “device” as used herein generically refers to an object being processed in accordance with the disclosure, and may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate, structure, or device is not limited to any particular base structure, underlying layer or overlying layer, patterned or un-patterned, but rather, is contemplated to include any such layer or base structure, and any combination of layers and/or base structures. The description may reference particular types of substrates, structures, or devices, but this is for illustrative purposes only.

Although this disclosure describes particular process steps as occurring in a particular order, this disclosure contemplates the process steps occurring in any suitable order. While this disclosure has been described with reference to illustrative embodiments, this description is not intended to be construed in a limiting sense. Various modifications and combinations of the illustrative embodiments, as well as other embodiments of the disclosure, will be apparent to persons skilled in the art upon reference to the description. It is therefore intended that the appended claims encompass any such modifications or embodiments.

What is claimed is:

1. A method for electronic design automation, the method comprising:
receiving a process design kit comprising an initial netlist and initial design rules of a standard cell for creating an integrated circuit;
generating, using an artificial intelligence/machine learning (AI/ML) placement model, a set of candidate layouts of the standard cell;
determining, using an AI/ML predictive model, initial values of a metric function for the set of candidate layouts;
identifying a subset of the set of candidate layouts that have the initial values of the metric function within a target range;
scaling one or more initial design rules to determine one or more scaled design rules;
generating, using the AI/ML placement model, a set of candidate scaled layouts of the standard cell;
determining, using the AI/ML predictive model, scaled values of the metric function for the set of candidate scaled layouts;
identifying a subset of the set of candidate scaled layouts that have the scaled values of the metric function within a scaled target range; and
ranking the one or more scaled design rules based on an impact of each scaled design rule on the scaled values of the metric function.

2. The method of claim 1, further comprising:
in response to determining that the scaled target range equals a desired target range:
identifying the subset of the set of candidate scaled layouts as one or more scaled layouts of the standard cell;
identifying respective values of the metric function for the one or more scaled layouts; and
updating the initial design rules based on the one or more scaled design rules.

3. The method of claim 1, further comprising, in response to determining that the scaled target range does not equal a desired target range, scaling the one or more scaled design rules.

4. The method of claim 1, wherein the AI/ML predictive model and the AI/ML placement model comprise graph neural network (GNN) models.

5. The method of claim 1, wherein the metric function comprises a function of a power metric, a performance metric, an area metric, and a cost metric.

6. The method of claim 5, wherein the performance metric comprises parasitic resistance and capacitance of a respective layout.

7. The method of claim 1, further comprising iteratively scaling the one or more scaled design rules until the scaled values of the metric function are within a desired target range.

8. A method for electronic design automation, the method comprising:
receiving a process design kit comprising an initial netlist and initial design rules of a standard cell for creating an integrated circuit;
generating, using an artificial intelligence/machine learning (AI/ML) placement model, a set of candidate layouts of the standard cell;
determining, using an AI/ML predictive model, initial values of a metric function for the set of candidate layouts;
identifying a subset of the set of candidate layouts that have the initial values of the metric function within a target range;
iteratively scaling the initial design rules until a scaled target range equals a desired target range, wherein each iterative scaling process comprises:
scaling one or more initial design rules to determine one or more scaled design rules;
generating, using the AI/ML placement model, a set of candidate scaled layouts of the standard cell;
determining, using the AI/ML predictive model, scaled values of the metric function for the set of candidate scaled layouts; and
identifying a subset of the set of candidate scaled layouts that have the scaled values of the metric function within a scaled target range;
identifying one or more candidate scaled layouts having values of the metric function within the desired target range as one or more scaled layouts of the standard cell;
identifying respective values of the metric function for the one or more scaled layouts;
updating the initial design rules based on one or more scaled design rules used to generate the one or more scaled layouts of the standard cell; and
ranking the one or more scaled design rules based on an impact of each scaled design rule on the scaled values of the metric function.

9. The method of claim 8, wherein using the AI/ML placement model comprises using a Monte Carlo simulation model.

10. The method of claim 8, wherein using the AI/ML placement model comprises using a Bayesian model.

11. The method of claim 8, wherein the AI/ML predictive model and the AI/ML placement model comprise graph neural network (GNN) models.

12. The method of claim 8, wherein the metric function comprises a function of a power metric, a performance metric, an area metric, and a cost metric.

13. The method of claim 12, wherein the performance metric comprises parasitic resistance and capacitance of a respective layout.

14. A system for electronic design automation, the system comprising:
one or more memories configured to store:
an artificial intelligence/machine learning (AI/ML) placement model;
an AI/ML predictive model; and
instructions; and
one or more processors operably coupled to the one or more memories and configured to execute the instructions, wherein, upon execution of the instructions by the one or more processors, the one or more processors are configured to:
receive a process design kit comprising an initial netlist and initial design rules of a standard cell for creating an integrated circuit;
generate, using the AI/ML placement model, a set of candidate layouts of the standard cell;
determine, using the AI/ML predictive model, initial values of a metric function for the set of candidate layouts;
identify a subset of the set of candidate layouts that have the initial values of the metric function within a target range;
scale one or more initial design rules to determine one or more scaled design rules;
generate, using the AI/ML placement model, a set of candidate scaled layouts of the standard cell;
determine, using the AI/ML predictive model, scaled values of the metric function for the set of candidate scaled layouts;
identify a subset of the set of candidate scaled layouts that have the scaled values of the metric function within a scaled target range; and
rank the one or more scaled design rules based on an impact of each scaled design rule on the scaled values of the metric function.

15. The system of claim 14, wherein the one or more processors are further configured to:
in response to determining that the scaled target range equals a desired target range:
identify the subset of the set of candidate scaled layouts as one or more scaled layouts of the standard cell;
identify respective values of the metric function for the one or more scaled layouts; and
update the initial design rules based on the one or more scaled design rules.

16. The system of claim 14, wherein the one or more processors are further configured to, in response to determining that the scaled target range does not equal a desired target range, scale the one or more scaled design rules.

17. The system of claim 14, wherein the AI/ML predictive model and the AI/ML placement model comprise graph neural network (GNN) models.

18. The system of claim 14, wherein the metric function comprises a function of a power metric, a performance metric, an area metric, and a cost metric.

19. The system of claim 18, wherein the performance metric comprises parasitic resistance and capacitance of a respective layout.

20. The system of claim 14, wherein the one or more processors are further configured to iteratively scale the one or more scaled design rules until the scaled values of the metric function are within a desired target range.
